(19) United States
(12) Patent Application Publication
(10) Pub. No.: US 2006/0275537 A1
(43) Pub. Date: Dec. 7, 2006

(54) Method and apparatus for field-emission high-pressure-discharge laser chemical vapor deposition of free-standing structures

(75) Inventors: James L. Maxwell, Jemez Springs, NM (US); Mats Boman, Jarlasa (SE)

Correspondence Address: LOS ALAMOS NATIONAL SECURITY, LLC, LOS ALAMOS NATIONAL LABORATORY, PPO. BOX 1663, LC/IP, MS A187, LOS ALAMOS, NM, 87545, US

(73) Assignee: The Regents of the University of California

(21) Appl. No.: 11/143,179

(22) Filed: Jun. 2, 2005

(51) Int. Cl. C23C 16/52

(52) U.S. Cl. 427/8

(57) ABSTRACT

A method of growing a free-standing structure, such as a fiber, rod, or tube. A laser beam having is focused on a terminal end of the fiber to heat the terminal end, and at least one gaseous precursor is provided into the beam. At least one electrode is located at a distance from the terminal end. The electrode is in electrical communication with the free-standing structure. A potential is applied between the terminal end and the at least one electrode. The applied potential creates a localized high pressure plasma in the vicinity of the terminal end, and generates reactive species from the gaseous precursor, and accelerates reactive species to the terminal end to grow the free-standing structure at an enhanced rate. An apparatus for growing fibers according to the method is also disclosed.

### STATEMENT REGARDING FEDERAL RIGHTS

This invention was made with government support under Contract No. W-7405-ENG-36 awarded by the U.S. Department of Energy. The government has certain rights in the invention.

### FIELD OF THE INVENTION

The present invention relates generally to free-standing structures, such as fibers. More particularly, the invention relates to an apparatus and methods for preparing fibers and other structures using plasma enhanced laser chemical vapor deposition.

### BACKGROUND OF THE INVENTION

Fibers are the simplest three-dimensional microstructures. Fibers find application in a variety of materials applications, including telecommunications, composites, textiles, nanoelectronics, and photonics. Fibers and fiber-like materials are also the basis for many emerging nano-scale (NEMS) and micro-scale electromechanical systems (MEMS) and devices.

The ability to synthesize, shape, place, orient, and assemble fibers is key to their application in such systems. Many existing methods for the production of spooled inorganic and organic fibers are often materials-specific. Such methods are frequently not amenable to manipulation into useful structures. Additional process steps are needed to cut, modify, and manually assemble bulk fibers. Most bulk production methods are also not amenable to the production of functionally graded (FG) fibers whose composition varies in functionally useful ways along either their lengths or radii. FG fibers have properties that can form the basis for new devices and systems.

Scale is also an important factor, as it becomes increasingly difficult to manually assemble fibers into systems as fiber size decreases. This is especially true for nano-scale fibers and nanotubes. Many mechanical devices have been developed simply to align micro-scale optical fibers to either form light sources and detectors, or to connect or switch signals from one optical fiber to another.

Many materials have yet to be utilized in useful forms such as fibers, simply because either their material properties are not amenable to existing production methods, or the optimal material phase is not thermodynamically stable at the temperatures required by current processing methods.

For example, one useful fiber material would be hafnium carbide (HfC), a refractory material with an extremely high melting point. The use of HfC in composite materials is limited, however, as it has generally only been grown in fiber-like form as random whiskers using chemical vapor deposition. Drawing HfC wire is impractical, as it is a brittle material. In addition, deposition kinetics for standard CVD or laser chemical vapor deposition of HfC is relatively slow, driving up the cost of HfC fiber production.

Diamond fibers would be extremely useful as well, both in composite materials and electronic devices. It is, however, impractical to create diamond fibers using traditional thermal CVD or laser chemical vapor deposition because the processing temperatures are greater than the temperature at which diamond becomes thermodynamically unstable. Thus, only graphite and other allotropes of carbon are obtained by these methods.

Current vapor deposition methods are limited in their ability to shape, orient, or assemble fibers, and, in some instances, are unable to achieve fiber growth in the temperature range in which the desired phase is thermodynamically stable. Therefore, what is needed is a method of preparing fibers or other free-standing structures comprising selected phases of high temperature materials. In addition, what is needed is a method that allows a wide range of materials to be deposited using a single deposition system. What is also needed is a method and apparatus that make it possible to modulate the composition of the fibers or other free-standing structures during growth to create functionally graded fibers or structures. Finally, what is needed is a method and apparatus that is capable of forming fibers of materials that would not ordinarily be available in fiber form.

### SUMMARY OF THE INVENTION

The present invention meets this and other needs by providing both a method and an apparatus for growing free-standing structures, such as, but not limited to, fibers of materials.

Accordingly, one aspect of the invention is to provide a method of growing a free-standing structure. The method comprises the steps of: providing the free-standing structure, the free-standing structure having a first end and a terminal end, wherein the first end is coupled to a substrate; focusing a laser beam end to heat the terminal end, the laser beam having a beam waist on the terminal; providing at least one gaseous precursor into the beam waist; disposing at least one electrode at a distance from the terminal end, wherein the at least one electrode is in electrical communication with the free-standing structure; and applying a potential between the terminal end and the at least one electrode. The applied potential creates a localized high pressure plasma in the vicinity of the terminal end and generates reactive species from the at least one gaseous precursor and accelerates the reactive species to the terminal end to grow the free-standing structure at an enhanced rate.

A second aspect of the invention is to provide a method of enhancing the growth rate of a free-standing structure having a terminal end. The method comprises the steps of: heating the terminal end with a laser beam to cause thermionic emission of electrons from the terminal end; providing an electrode, the electrode being in electrical communication with the free-standing structure and disposed at a distance from the terminal end; applying a potential between the terminal end and the electrode to cause field emission from the terminal end; and providing at least one gaseous precursor to the vicinity of the terminal end, wherein the potential between the terminal end and the electrode creates a localized high pressure plasma in the vicinity of the terminal end, generates reactive species from the at least one gaseous precursor, and accelerates the reactive species to the terminal end to enhance the growth rate of the free-standing structure.

A third aspect of the invention is to provide a method of growing at least one fiber. The method comprises the steps of: depositing one of a seed and a catalyst on a substrate; heating one of the seed and the catalyst with a laser beam, wherein the laser beam has a beam waist; providing at least one gaseous precursor to the beam waist to decompose the at least one gaseous precursor to form the at least one fiber, the at least one fiber having a first end coupled to a substrate and a terminal end; heating the tapered end with the laser beam to cause thermionic emission of electrons from the terminal end; providing an electrode, the electrode being in electrical communication with the fiber and disposed at a distance from the terminal end; applying a potential between the terminal end and the electrode to cause field emission of electrons from the terminal end; and providing at least one gaseous precursor to the vicinity of the terminal end, wherein the potential between the terminal end and the electrode creates a localized high pressure plasma in the vicinity of the terminal end, and wherein the localized high pressure plasma generates reactive species from the at least one gaseous precursor and accelerates the reactive species to the tapered end to enhance the growth rate of the fiber.

A fourth aspect of the invention is to provide an apparatus for growing a free-standing structure. The apparatus comprises: a support structure for supporting the free-standing structure during growth; at least one gaseous precursor source; a laser that is capable of focusing on a terminal end of the free-standing structure during growth, wherein the laser is capable of heating a growth zone proximate to the terminal end and decomposing species in the growth zone; and at least one electrode, wherein the at least one electrode is in electrical communication with the free-standing structure during growth and is positioned at a distance from the growth zone, and wherein a potential applied between the at least one electrode and the growth zone generates a high pressure plasma and reactive species in the growth zone and accelerates the reactive species to the terminal end to enhance the growth rate of the free-standing structure.

These and other aspects, advantages, and salient features of the present invention will become apparent from the following detailed description, the accompanying drawings, and the appended claims.

### BRIEF DESCRIPTION OF THE DRAWINGS

FIG. 1 is a schematic diagram of an apparatus for growing free-standing structures, showing the initial growth of a fiber without plasma enhancement;

FIG. 2 is an image of carbon fibers grown from ethylene using the methods and apparatus described herein;

FIG. 3 is a schematic diagram of an apparatus for growing free-standing structures showing steady growth of a fiber with plasma enhancement;

FIG. 4 is a flow diagram of a method of growing free-standing structures; and

FIG. 5 is a plot of the axial fiber growth rate of as a function of pressure.

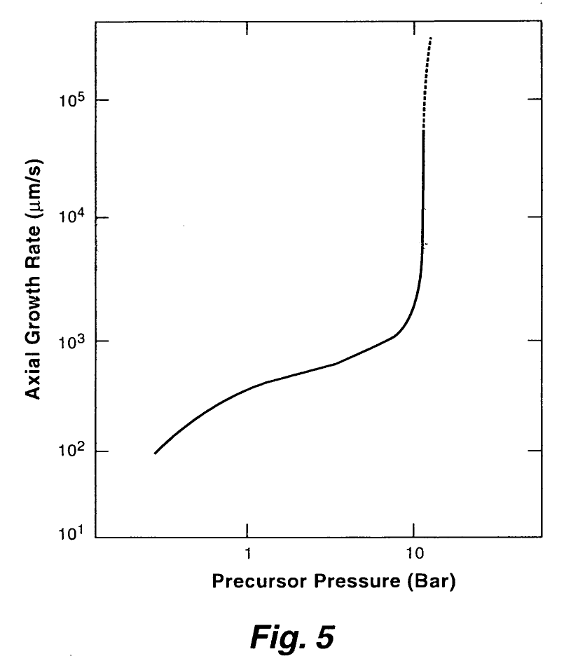

### DETAILED DESCRIPTION

In the following description, like reference characters designate like or corresponding parts throughout the several views shown in the figures. It is also understood that terms such as “top,” “bottom,” “outward,” “inward,” and the like are words of convenience and are not to be construed as limiting terms. In addition, whenever a group is described as either comprising or consisting of at least one of a group of elements and combinations thereof, it is understood that the group may comprise or consist of any number of those elements, either individually or in combination with each other.

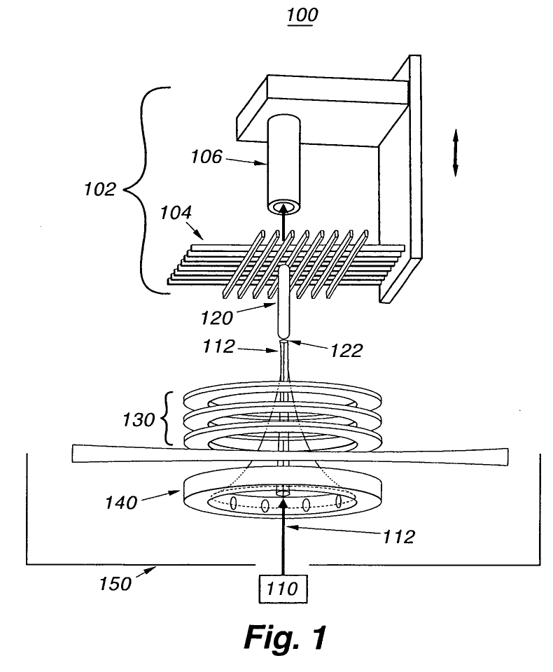

Referring to the drawings in general and to FIG. 1 in particular, it will be understood that the illustrations are for the purpose of describing a particular embodiment of the invention and are not intended to limit the invention thereto. Turning now to FIG. 1, an apparatus for preparing free-standing structures, as described herein, is shown. For the purposes of understanding the invention, a “free-standing structure” is understood to be a fiber, rod, or tube. While the following description refers to a “fiber,” it is generally applicable to rods and tubes as well. Apparatus 100 comprises a support structure 102 for supporting at least one fiber 120 during the growth process. Support structure 102 may serve as a substrate for fiber 120 during initial growth of fiber 120, and therefore should be chemically inert under conditions that are used to grow fiber 120. In the embodiment shown in FIG. 1, support structure 102 further includes a meshed substrate 104 to permit bulk fluid flow in the space behind the growing fiber 120 and a nozzle 106 for removal of gaseous byproducts and recycling of unused gaseous precursors.

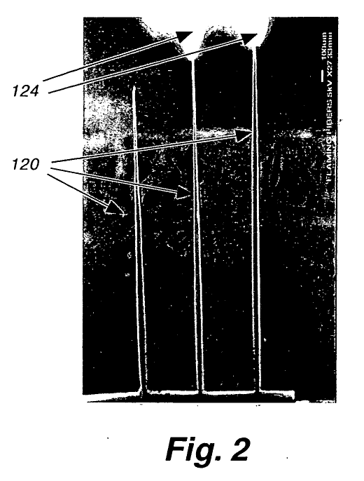

Apparatus 100 also includes at least one laser 110 such as, but not limited to a Nd:YAG laser (such as a frequency doubled laser), an argon laser, a Ti:sapphire Nd:Yag-pumped femtosecond laser, and the like. Laser 110 produces a laser beam 112 that is substantially coaxially aligned with the major axis (i.e., the axis running the length of fiber 120) of fiber 120. Laser beam 112 is focused on tip 122, and impinges upon the terminal end 122 of fiber 120, thereby heating the terminal end 122. Terminal end 122 and the region immediately proximate thereto are referred to as the “growth zone.” The shape of tip 122 depends primarily upon the growth dynamics and is usually tapered or pointed. The heating of terminal end 122 by laser beam 112 is sufficient to cause thermionic emission of electrons from terminal end 122. Terminal end 122 is typically distal from support structure 102. FIG. 2 is a micrograph of carbon fibers 122, each having terminal end 122.

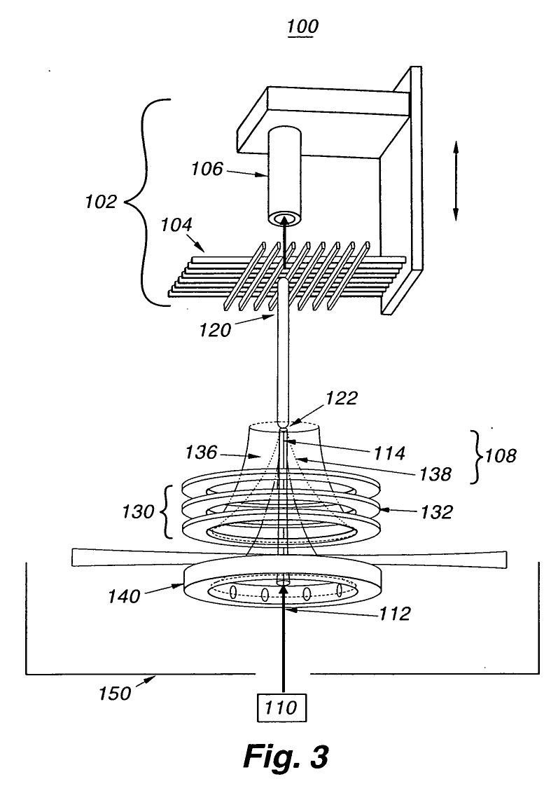

FIG. 3 is a schematic representation of apparatus 100, showing steady growth of fiber 120 with plasma enhancement. At least one electrode 130 is located at a distance 108 from, and in opposition to, terminal end 122. The at least one electrode 130 is in electrical communication with terminal end 122, usually through support structure 102. A power source (not shown) provides a bias voltage, or potential, between the at least one electrode 130 and terminal end 122. The at least one electrode 130 usually includes an anode 134, and terminal end 122 serves as a cathode. When gases are injected into the reaction zone between terminal end 122 and the at least one electrode, the potential between the at least one electrode 130 and terminal end 122 generates a localized high pressure plasma 136 that creates reactive species. In addition, the potential causes terminal end 122 to act as a field emitter. In FIG. 2, field emission plumes 124 are seen emanating from terminal ends 122 of two of the fibers 120. Thus, terminal end 122 provides electrons to a reaction zone 138 by both thermionic and field emission. The electrons emitted by these two processes serve to ionize gaseous precursor species that are provided to the plasma by at least one gaseous precursor source 140. The electric field that is present between the at least one electrode 130 and terminal end 122 directs and accelerates the resulting ions toward terminal end 122, where they react to deposit the material comprising fiber 120, causing fiber 120 to grow in the direction of the electric field and towards the at least one electrode 130.

As fiber 120 continues to grow, the distance 108 between the at least one electrode 130 and terminal end 122 is preferably maintained so that the positions of terminal end 122, the focus of beam 112, and the generated plasma remain stationary. If distance 108 changes during fiber growth, then the current at constant voltage will change as well, affecting the composition and acceleration of gaseous species in a nonlinear fashion. To achieve this, the at least one electrode 130 and support structure 102 are movable with respect to each other. A positioning system (not shown) may provide a means for moving one of support structure 102 and the at least one electrode. In one embodiment, support structure 102 comprises a movable stage. In one embodiment, the positioning system includes a Fabry-Perot interferometer, a laser ranging system, or the like, to track the position of the terminal end 122. As fiber 120 grows, support structure 102 moves away from the at least one electrode 130 to maintain distance 108 between terminal end 122 and the at least one electrode 130. Similarly, the positioning system allows the at least one electrode 130 to be movable in a direction away from growing fiber 120. Alternatively, distance 108 may be maintained by collecting fiber 120 as it continues to grow. Such collecting mechanisms include, but are not limited to, collecting bins, spools, take up reels, and the like.

To properly maintain distance 108 at a substantially constant value, distance 108 may be measured and monitored by a measurement system (not shown) that may include, for example, either a laser-ranging or a laser-tracking system. By performing laser ranging with the deposition beam, the outward growth of the fiber can be readily tracked to either maintain a constant focus or switch from one electrode to another as the fiber grows, so that the plasma remains concentrated only at the terminal end 122. In one embodiment, a feedback loop that receives a signal generated by the measurement system and directs the positioning system to maintain the distance 108 at a set value. Alternatively, the signal generated by the measurement system may include a voltage sensor for detecting the potential between terminal end 122 and the at least one electrode 130. The signal generated by the voltage sensor may then be directed to a power supply for adjusting the potential between terminal end 122 and the at least one electrode 130.

In one embodiment, the at least one electrode 130 includes a grounding plate 132, an anode 134, and a secondary cathode 136 for adjusting the acceleration of various ionic species toward terminal end 122. The at least one electrode 130 is coaxially aligned with laser beam 112 to direct growth of fiber 120 in the direction of the electric field and maintain focus of laser beam 112 on terminal end 122. As shown in FIG. 1, the at least one cathode 130 comprises three concentric rings. The at least one electrode 130 may have a wide variety of geometries and still be effective.

Reactive precursor gases are provided for growth of fiber 120 by at least one gaseous precursor source 140. The at least one gaseous precursor source 140 provides at least one reactive precursor gas to laser beam 112. In one embodiment, shown in both FIGS. 1 and 3, the at least one gaseous precursor source 140 is a ring injector that is coaxially aligned with laser beam 112 and the at least one electrode 130. When a co-axial forced flow of precursor gases is directed at the fiber co-incident with the focused beam, not only does large mass transport occur, but the composition and structure of the deposited material is determined by the voltage between the fiber and counter-electrode (in constant current mode). Other configurations that are well known in the art, such as a plurality of nozzles, effusion cells, injectors, and the like, may also be used.

Apparatus 100 may also be adapted to grow a plurality of fibers 120. In one 10 embodiment, fibers 120 form an array, and a plurality of laser beams 112 are provided to the terminal end 122 of each fiber 120, by either a plurality of lasers 110, or splitting a single laser beam 112 generated by a single laser 120.

The growth of fiber 120 is conducted in a controlled atmosphere, with pressures ranging from about 0.5 bar up to hyperbaric pressures (10-100 bar). Accordingly, support structure 102, fiber 120, the at least one electrode 130, and the at least one gaseous precursor source 140 are disposed within a growth chamber 150, that is capable of providing and maintaining a controlled atmosphere at pressures ranging from about 0.5 bar up to 100 bar. Laser 110 may be located outside growth chamber 150. Accordingly, growth chamber 150 may include a laser window 114 to allow laser beam 112 to enter growth chamber 150 and heat terminal end 122.

The invention also includes a method for preparing fibers and other structures. Through the use of the invention, high-quality inorganic fibers having a desired orientation and microstructure may be prepared rapidly and collected or spooled for later use.

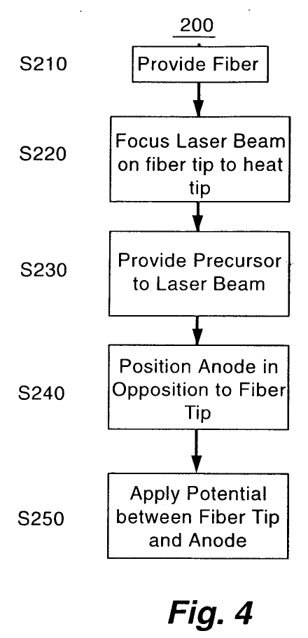

A flow diagram of the basic method of making fibers is shown in FIG. 4. In step S210, at least one fiber 120 is provided. The fiber 120 may grown in situ, using support structure 102 as a substrate. Initial growth of fiber 120 may be achieved using, for example, the LCVD method described below. Alternatively, a fiber 120 that has been previously grown may be provided and affixed to support structure 102.

FIG. 1 shows apparatus 100 and fiber 120 during the initial stages of fiber growth. Fiber growth is initiated using a solid seed crystal (or catalyst) attached to a support. In one embodiment, the support is retractable. A short fiber is initiated from the seed crystal or catalyst using traditional laser chemical vapor deposition (LCVD). One or more gaseous chemical precursors are provided to the focal point of a laser beam. The incident laser beam induces a photochemical or photothermal reaction with the gaseous precursors. The fiber grows from the seed 10 or catalyst into free space in the direction of the laser beam. If the laser beam is oriented or moved slowly as the fiber grows, fiber growth occurs in the direction of the laser beam. Fresh, unreacted gaseous precursor is continuously supplied, and by-products are removed by forced-flow, convection, or combinations thereof. The short fiber and attached seed are then placed in a gaseous environment at a hyperbaric pressure (i.e., a pressure greater than 1 bar) and at least one precursor gas is provided to the fiber 120. For the purpose of describing the invention, ‘precursor gas’ is understood to mean either a single gaseous precursor or multiple gaseous precursors. The precursor gas is provided to the fiber or seed as a pulsed flow, constant flow, or combinations thereof. At least one of these flows of gas may be preheated using a laser, heated nozzles, induction heating, electric arcs, or the like.

In step S220, laser beam 112 is focused on terminal end 122 to heat terminal end 122. Laser beam 112 is directed at the short fiber or seed so that the laser heats the terminal end 122 of fiber 120. The terminal end of the fiber is typically tapered or pointed (FIG. 2 is a micrograph of carbon fibers 120, each having terminal end 122) due at least in part to growth kinetics. The laser heating produces thermionic emission from the terminal end 122 of the fiber. Thermionic emission serves to control and enhance the growth rate and properties of the growing fiber. FIG. 2 shows thermionic emission plumes 124 emanating from terminal ends 122 of carbon fibers 120.

In step S230, at least one gaseous precursor is provided to the “Waist” 114 (FIG. 2) of the focused laser beam. The “waist” 114 of the focused laser beam here refers to the diameter of laser beam 112 in the vicinity of terminal end 122.

In step S240, at least one anode 134 is positioned in opposition to the terminal end 122 of the fiber, and a bias voltage is applied between the terminal end 122 of the fiber and the anode 134 (step S250) as the laser beam 112 heats the terminal end 122. The bias voltage is typically, but not necessarily, less than about 2000 V, because the gap between the anode 134 and terminal end 122 is small, and the gas pressure within chamber is large—typically greater than about 0.5 bar. The electric field can be pulsed to prevent arcing over the short gap. The bias voltage generates a stable discharge in the high-pressure gas. Partially ionized species in the discharge are accelerated toward, and concentrated at, the strong field at the terminal end 122 of fiber 120, which acts as the cathode. At the same time, electrons emitted from the laser-heated terminal end 122 by both thermionic emission and field emission travel to the anode 134. Field emission is induced from the terminal end 122 using an anode 134 opposing the terminal end 122 of the growing fiber. This field emission also enhances both the growth rate and properties of the fiber. For example, by varying at least one of the laser heating and the bias voltage, materials having a desired orientation and crystal structure may be generated within the fiber. Similarly, specific phases of materials, such as, but not limited to, diamond-like carbon (DLC) may be generated by applying a bias voltage within a chosen range.

The method described herein may be either a continuous or step-wise process; the overall composition, or relative concentrations, of precursor gases may be adjusted during fiber growth. One possible result of adjusting this composition is to produce a fiber having at least one composition gradient. For example, a fiber that includes both boron nitride and carbon may be prepared, for example, by using a precursor gas mixture of a boron-containing gas (such as diborane) and a nitrogen-containing gas (such as gaseous nitrogen) during the initial phases of fiber growth. After fiber growth has begun, a gaseous carbon precursor can be introduced into the gas mixture at a controlled rate to yield a graded portion with increasing carbon content in the fiber, as the fiber continues to grow. The growth of this type of fiber employs a precursor gas (nitrogen), which is difficult to decompose. In this case, the concentration of ions (here, nitrogen ions) that result from the decomposition may be controlled by adjusting the bias voltage applied between the terminal end 122 and the anode 134. In this way, the fiber composition—here, the amount of nitrogen present in the fiber—may be controlled independently of the terminal end temperature.

The use of an opposing anode 134 and application of a bias voltage distinguishes the present method and apparatus from traditional laser CVD processes. The fiber is electrically connected to the overall circuit and forms a portion thereof. For traditional LCVD, the temperature of the terminal end 122 controls the concentration of any intermediates formed from decomposition of precursor gases and the transport rate of these intermediates to the terminal end 122. In the present invention, however, the production of intermediates is not entirely dependent on the temperature at the terminal end 122 and may therefore be adjusted independently from the temperature at the terminal end 122. Through the use of the laser 110, the temperature of the fiber 120 is kept within a temperature range that is sufficiently high to drive the reaction for fiber growth, but not high enough to cause a change in the phase of the already deposited fiber material. Meanwhile, the composition of the precursor gases adjacent to the reaction zone can be controlled via the bias voltage. As a result, the composition and microstructure of the fiber may be at least partially decoupled from each other. The bias voltage can be varied to produce a specific concentration of gaseous species independent of the surface temperature of the fiber. Without the ability to independently control the terminal end temperature and the available species for deposition at the terminal end 122, only a limited range of microstructures and compositions may be produced.

Another aspect of the invention relates to the ability to produce species at the terminal end 122 independently of the temperature of the terminal end 122, thus allowing a much wider range of microstructures and compositions than what is typically accessible using traditional LCVD. Some materials are difficult to grow by conventional CVD methods, as the temperature needed for deposition to occur is greater than the temperature at which the material is thermodynamically stable. The deposition method described herein allows for highly localized heating of the terminal end 122, allowing the rest of the fiber to be maintained at a temperature where the desired phase is stable. This aspect of the invention may be illustrated by the growth of a diamond fiber. In the absence of oxygen or other oxidizing materials, diamond becomes unstable and is converted to graphite at temperatures exceeding about 1100-1500° C. Therefore, in order to avoid conversion into graphite, diamond should not be heated to a temperature of 1100° C. or greater. In the preparation of diamond fibers according to the invention, the growing fiber is kept at a temperature below 1000° C. to maintain the diamond phase within the fiber. In one embodiment, diamond-like carbon may be grown at laser-induced temperatures in a range from about 600° C. to about 800° C., where methane is the precursor gas, or carbon source. The carbon source concentration is in a range from about 2 percent to about 5 percent, with the remainder of the gas comprising hydrogen and a small (<1%) amount of xenon or krypton. The optimal DC voltage varies with the distance between the electrode and the terminal end 122 of the DLC fiber (i.e., the cathode). The voltage is generally in a range between about 100 V to about 400 V when the gap between the anode 134 and terminal end 122 is below about 1 mm.

Ordinarily, hydrogen ions, which are needed for etching graphite, are generated from hydrogen gas by heating the gas to a temperature of about 2000° C. In the present invention, rather than heating hydrogen to about 2000° C., hydrogen ions may be generated by applying a bias voltage between the anode 134 and the terminal end 122 to generate a plasma. The diamond phase is retained in the fiber by producing hydrogen ions by applying the bias voltage while maintaining the terminal end temperature below 1000° C. Thus, through the use of the plasma-generating bias voltage, the temperature at the terminal end surface can be maintained below 1000° C. while the required hydrogen ions are generated to sustain continued growth of the diamond fiber. Inorganic nanotubes may be grown in a similar fashion. In this instance, nano-sized crystals, having dimensions of up to 100 nm, are used as seed crystals.

The fiber temperature, the local pressure of reactant gases in the vicinity of the terminal end 122, and the flow rate of gaseous precursors all influence the grain size of materials that form the fiber. Elevated temperatures tend to produce larger grains and single crystals, whereas higher pressures and flow rates tend to produce more amorphous deposits. Introducing a high-pressure plasma influences nucleation rates during deposition that produce a particular grain size and microstructure. An increase in nucleation rate tends to produce amorphous deposits, while an increase in the growth rate of individual grains tends to produce large single crystals.

In order to obtain a fiber with a desired grain structure, the temperature is should be maintained within a particular range. However, this temperature may not be optimal for preparing a fiber—or a section of a fiber—having a desired composition or ratio of two different materials. However, by applying the bias voltage between the anode 134 and terminal end 122 to produce the high pressure plasma, allows the production of desired grain sizes and composition or ratio between two materials can be maintained.

Fiber temperature influences the diameter and shape of the fiber that is obtained. If either an hourglass-shaped or tapered fiber is desired, the laser power can be adjusted to obtain these shapes. Normally, the variation in laser power would affect not only the structure, but also the composition of the fiber. However, by varying the laser power and the bias voltage, the present invention allows independent control of the composition and structure of the fiber. If, for example, a tapered or hourglass-shaped fiber with a constant composition or microstructure is desired, the laser power would be adjusted to provide this shape while the bias voltage would be adjusted in order to maintain the composition of the fiber during fiber growth.

Another aspect of the present invention is related to preparing fibers having a desired microstructure that provide controlled properties. In one example, a carbon fiber having a first microstructure (graphite, for example) could be initiated from a catalyst or seed crystal. After some period of time, the growth temperature is maintained while the bias voltage is readjusted to provide another microstructure, such as, for example, diamond-like carbon. In this way, a fiber having a conducting portion (i.e., the graphite portion) and a dielectric portion (i.e., the diamond-like carbon portion) may be prepared. This strategy of adjusting the bias voltage to prepare fibers with special, controlled properties is a unique aspect of this invention.

The fiber growth rate is largely determined by the transport rate of reactants, intermediates, and products to and from the reaction—or growth—zone, which is a small focused spot at or near the terminal end 122 of the fiber. Single fiber growth rates in excess of 10 cm/sec are achievable, even without forced flow or plasma enhancement, thereby providing rapid fiber growth through bulk transport.

When heated by the laser beam, the narrow terminal end 122 of the growing fiber functions as a field emission source. Electrons flow readily from the terminal end 122 by thermionic emission, which may be enhanced through careful selection of the pulse energy, duration, and wavelength of the laser beam. Field-emission can be generated at multiple terminal ends where the height of the individual terminal ends are within several hundred microns of each other, thus enabling parallel growth of fiber arrays and ropes. When an opposing electrode (anode) is placed near the growing fiber (for example, within about 0.5 mm) and a voltage differential is applied between the electrode and fiber, a localized high-pressure plasma is generated between the electrode and the terminal end 122. This phenomenon can be enhanced through careful selection of the laser pulse energy, duration, and wavelength.

Intermediate species generated within the plasma are accelerated toward the reaction zone and the cathode and concentrated by the strong field at the terminal end, where growth occurs. The composition of species between the terminal end and the cathode can also be controlled through the application of one of a relatively low-voltage oscillating, pulsed, or direct current (DC) electric field. Increasing the concentration of suitable species enhances growth rates. An extremely efficient system of transporting, converting, and growing fibers is created, with great control over the properties and composition of deposited materials, with the lowest possible voltage being applied.

The voltage between the anode 134 and cathode depends on gap distance; terminal end sharpness; terminal end temperature; fiber resistivity; bias (DC vs. AC, frequency, etc.); bulk gas flow rate, if any; and overall gas pressure and composition. The deposition rate increases by orders of magnitude, and the required deposition temperature is reduced, allowing for economic growth of valuable metastable materials, such as diamond-like carbon, which could not ordinarily be grown using LCVD Also, the plasma produced after applying the bias voltage between the anode 134 and the terminal end 122 provides intermediate species that otherwise would not be available for the laser-induced reaction; the electric field generates needed reactive species in the gas flow, and the laser induces a reaction using these reactive species.

The elements of field emission, thermionic emission, LCVD, and localized high-pressure plasma are brought together in the present invention.

Fibers of other materials that may be prepared according to this invention include, but are not limited to, refractory metals, transition metals, and lanthanum group elements, including high Z (atomic number) metals such as tungsten, hafnium, gold, gadolinium, and the like; superhard or refractory materials, such as, diamond, carbides, nitrides, and silicides that are included in high-strength composites and textiles; and ternary compounds, such as BCₓN, HfₓB_{y}N_{z}, and the like. Non-limiting examples of such materials include WC-DLC composites, cubic boron nitride (c-BN), and long crystals of diamond.

While typical embodiments have been set forth for the purpose of illustration, the foregoing description should not be deemed to be a limitation on the scope of the invention. Accordingly, various modifications, adaptations, and alternatives may occur to one skilled in the art without departing from the spirit and scope of the present invention.

We claim:

1. A method of growing a free-standing structure, the method comprising the steps of:
a) providing the free-standing structure, the free-standing structure having a first end and a terminal end, the first end being disposed on a substrate;
b) focusing a laser beam on the terminal end to heat the terminal end, wherein the laser beam has a beam waist;
c) providing at least one gaseous precursor into the waist;
d) disposing at least one electrode at a distance from the terminal end, wherein the at least one electrode is in electrical communication with the free-standing structure; and
e) applying a potential between the terminal end and the at least one electrode, wherein the applied potential creates a localized high pressure plasma in the vicinity of the terminal end, and generates reactive species from the at least one gaseous precursor and accelerates the reactive species to the terminal end to grow the free-standing structure at an enhanced rate.

2. The method according claim 1, wherein the step of providing a free-standing structure comprises:
a) depositing one of a seed and a catalyst on the substrate;
b) heating the catalyst with the laser beam;
c) providing the at least one gaseous precursor to the waist; and
d) decomposing the at least one gaseous precursor to form the free-standing structure.

3. The method according to claim 1, wherein the free-standing structure comprises at least one of a refractory metal, a transition metal, a lanthanum group element, a refractory material, diamond, and combinations thereof.

4. The method according to claim 3, wherein the refractory material is one of a carbide, a nitride, and a boride.

5. The method according to claim 1, wherein the method is carried out in a reaction chamber, and wherein the pressure within the reaction chamber is in a range from about 1 bar to about 100 bar.

6. The method according to claim 5, wherein the method is carried out in a reaction chamber, and wherein the pressure within the reaction chamber is in a range from about 1 bar to about 10 bar.

7. The method according to claim 1, further comprising the step of maintaining the distance at a substantially constant value.

8. The method according to claim 7, wherein the at least one electrode and the terminal end are movable with respect to each other.

9. The method according to claim 8, wherein the free-standing structure is drawn away from the laser focus such that the high pressure plasma and laser focus remain stationary.

10. The method according to claim 8, wherein the anode is drawn away from the terminal end of the free-standing structure to maintain the distance at a substantially constant value.

11. The method according to claim 7, further including the step of continuously measuring the distance.

12. The method according to claim 7, wherein the step of continuously measuring the distance comprises measuring the distance by one of laser-ranging and laser tracking.

13. The method according to claim 1, wherein the potential between the free-standing structure and the at least one electrode is maintained at a substantially constant value.

14. The method according to claim 13, wherein the step of applying a potential between the terminal end and the electrode comprises applying a potential of up to about 2000 V between the terminal end and the electrode.

15. The method according to claim 1, wherein the step of applying a potential between the terminal end and the at least one electrode comprises applying one of an oscillating electric field and a pulsed electric field.

16. The method according to claim 1, wherein the step of focusing a laser beam on the terminal end to heat the terminal end causes thermionic emission from the terminal end.

17. The method according to claim 1, wherein the free-standing structure is a fiber, rod, or tube.

18. A method of enhancing the growth rate of a free-standing structure having a terminal end, the method comprising the steps of:
a) heating the terminal end with a laser beam to cause thermionic emission from the terminal end;
b) providing an electrode, the electrode being in electrical communication with the free-standing structure and disposed at a distance from the terminal end;
c) applying a potential between the terminal end and the electrode to cause field emission from the terminal end; and
d) providing at least one gaseous precursor to the vicinity of the terminal end, wherein the potential between the terminal end and the electrode creates a localized high pressure plasma in the vicinity of the terminal end and generates reactive species from the at least one gaseous precursor and accelerates the reactive species to the terminal end to enhance the growth rate of the free-standing structure.

19. A method of growing at least one fiber, the method comprising the steps of:
a) depositing one of a seed and a catalyst on the substrate;
b) heating the catalyst with a laser beam, wherein the laser beam has a beam waist;
c) providing the at least one gaseous precursor to the beam waist to decompose the at least one gaseous precursor to form the at least one fiber, the at least one fiber having a first end coupled to a substrate and a terminal end;
d) heating the terminal end with the laser beam to cause thermionic emission from the terminal end;
e) providing an electrode, the electrode being in electrical communication with the fiber and disposed at a distance from the terminal end;
f) applying a potential between the terminal end and the electrode to cause field emission from the terminal end; and
e) providing at least one gaseous precursor to the vicinity of the terminal end, wherein the potential between the terminal end and the electrode creates a localized high pressure plasma in the vicinity of the terminal end, and wherein the localized high pressure plasma generates reactive species from the at least one gaseous precursor and accelerates the reactive species to the terminal end to enhance the growth rate of the fiber.

20. An apparatus for growing free-standing structure, the apparatus comprising:
a) a support structure for supporting the free-standing structure during growth;
b) at least one gaseous precursor source;
c) a laser that is capable of focusing on a growth zone of the free-standing structure during growth, wherein the laser is adapted to heat the growth zone and generate thermionic emission from a terminal end of the free-standing structure; and
d) at least one electrode, wherein the at least one electrode is in electrical communication with the fiber during growth and is positioned at a distance from the terminal end, wherein a potential applied between the at least one electrode and the terminal end generates a localized high pressure plasma, and wherein at least one precursor gas is supplied by the gaseous precursor source to the plasma.

21. The apparatus according to claim 20, further including a positioning system for adjusting the position of at least one of the at least one electrode and the support structure.

22. The apparatus according to claim 21, further including a measurement system for detecting and measuring a distance between the at least one electrode and the growth zone.

23. The apparatus according to claim 22, wherein the measurement system comprises one of a laser-ranging system and a laser tracking system.

24. The apparatus according to claim 22, further including a feedback loop that receives a signal from the measurement system and directs the positioner to maintain the distance.

25. The apparatus according to claim 20, further including a voltage sensor for detecting the potential between the terminal end and the at least one electrode.

26. The apparatus according to claim 25, further including a power supply for adjusting the potential between the terminal end and the at least one electrode.
